(19) United States
(12) Patent Application Publication
(10) Pub. No.: US 2010/0184292 A1
(43) Pub. Date: Jul. 22, 2010

(54) SYSTEMS, METHODS AND SLURRIES FOR CHEMICAL-MECHANICAL ROUGH POLISHING OF GAAS WAFERS

(76) Inventors: Tan Kaixie, San Francisco, CA (US); Zhang Jie, San Jose, CA (US); Yang Sangui, Beijing (CN)

Correspondence Address: DLA PIPER LLP (US ), 2000 UNIVERSITY AVENUE, EAST PALO ALTO, CA, 94303-2248, US

(21) Appl. No.: 12/607,862

(22) Filed: Oct. 28, 2009

(30) Foreign Application Priority Data
Jan. 22, 2009 (CN) 200910000511.2

(51) Int. Cl. H01L 21/302; C09K 13/00; H01L 21/306

(52) U.S. Cl. 438/693; 252/79.1; 156/345.14; 257/E21.23

(57) ABSTRACT

Chemical polishing systems, methods and slurries are disclosed for the chemical-mechanical rough polishing of GaAs wafers. An exemplary polishing slurry consistent with the innovations herein may comprise dichloroisocyanurate, sulfonate, pyrophosphate, bicarbonate and silica sol. An exemplary chemical polishing method may comprise polishing a wafer in a chemical polishing apparatus in the presence of such a chemical polishing solution. Chemical polishing solutions and methods herein make it possible, for example, to improve wafer quality, decrease costs, and/or reduce environmental pollution.

### CROSS-REFERENCE TO RELATED APPLICATION(S) INFORMATION

This application is based upon and claims benefit/priority of prior Chinese patent application No. 200910000511.2, filed Jan. 22, 2009, which is incorporated herein by reference in entirety.

### BACKGROUND

1. Field

The present innovations relate to chemical-mechanical rough polishing of gallium arsenide (GaAs) wafers as well as systems, methods and slurries consistent therewith.

2. Description of Related Information

GaAs is an important semiconductor material, developed more recently than Ge and Si to meet performance demands in semiconducting and semi-insulating devices. In certain applications and fields, GaAs crystals perform better than Ge and Si. For example, GaAs has an electron mobility about 6 times higher and can operate at higher frequencies than Si, and is thus a good material for high-speed integrated circuits and electronic devices. Monocrystalline GaAs wafers are mainly used in microwave and mm-wave communication fields, such as mobile phone, satellite transmission broadcast, radar system and other/related areas of advanced electronics, national defense, etc. Owing to its excellent photoelectric properties, GaAs is also used extensively in laser devices and light emission diode (LED) applications. Developments in these technologies coupled with expanding use of monocrystalline gallium arsenide has fostered a rapid increase in demand for GaAs products of higher quality and lower cost. GaAs manufacturers use a variety of efforts to improve product quality and reduce cost, including attempts to reduce adverse environmental impacts such as pollution stemming from chlorine (Cl₂) volatilization of wafer polishing solutions and slurries.

In general, GaAs wafers are cut from a GaAs crystal ingot by a metal saw or a wire saw, then undergo further processing, including grinding, chemical mechanical polishing, chemical polishing, and special cleaning, before being packaged for delivery to customers. The processed GaAs crystal wafers supplied to customers have smooth, mirror-like main surfaces, and possess physical properties satisfying certain requirements. Most customers typically then add different monocrystalline layers of various thicknesses onto the GaAs crystal wafers, i.e., they deposit further device layers on the mono-crystalline substrate surface, to provide devices with different functions.

During chemical-mechanical rough polishing and chemical fine polishing processes, different polishing slurries and solutions are used. In particular, in chemical-mechanical rough polishing, polishing slurries distinct from those employed for fine polishing are used.

Chemical-mechanical rough polishing may be implemented via processes such as the following. First, wafers may be etched by a chemical-mechanical rough slurry, wherein etched materials are mechanically removed by colloidal silica contained in the slurry. This rough polishing results in surfaces of appropriate flatness and properties, such that a chemical fine polishing process may then be provided to the wafers. Once rough polishing is complete, wafers typically undergo a chemical fine polishing process that is characterized by minimal additional surface removal (i.e., minimal material removed from the wafer) in accordance with various customer requirements. Accordingly, the quality of wafers after chemical-mechanical rough polishing is closely related to the quality and wafer yield of wafers resulting from the chemical fine polishing process. In general, chemical-mechanical rough polishing processes may involve removal of a relatively large thickness of the wafer, and are thus more costly. Such rough polishing can account for 90% of the cost associated with all (rough and fine) polishing processes. In addition, chemical-mechanical rough polishing processes are typically of much longer duration. As such, innovations in chemical-mechanical rough polishing can provide substantial and important advantages to production of GaAs wafers.

However, existing methods and solutions like these suffer drawbacks such as wafers having poor surface quality and generation of dangerous and/or caustic pollutants. Further, existing polishing solutions often leave GaAs crystal wafers contaminated with metal ions. Accordingly, electrical devices prepared using these wafers may suffer a variety of related drawbacks and defects such as increased leakage current, reduced service life, and failures, and the like. As such, there is a need in the art for improved chemical polishing solutions that enable creation of GaAs crystal wafers of high quality, while minimizing production costs, pollution and/or related problems.

### SUMMARY

Systems, methods and slurries consistent with the innovations herein are directed to chemical-mechanical rough polishing of GaAs wafers.

In exemplary implementations, there are provided method and slurries for chemical-mechanical rough polishing gallium arsenide (GaAs) wafers involving solutions comprising an alkali metal dichloroisocyanurate or ammonium dichloroisocyanurate, an alkali metal acid pyrophosphate or ammonium pyrophosphate, a silica sol, an alkali metal bicarbonate or ammonium bicarbonate, an alkali metal sulfonate or ammonium sulfonate, and optionally one or more solvents.

It is to be understood that both the foregoing summary and the following detailed description are exemplary and explanatory only and are not restrictive of the disclosure. Further features and/or variations may be provided in addition to those set forth herein. For example, the present disclosure may be directed to various combinations and subcombinations of the disclosed features and/or combinations and subcombinations of several further features disclosed below in the detailed description.

### DESCRIPTION OF THE DRAWINGS

The accompanying drawings, which constitute a part of this specification, illustrate various implementations and aspects of the present invention and, together with the description, explain the principles of the invention. In the drawings:

FIG. 1 is an illustration showing a schematic cross-sectional view of an exemplary chemical-mechanical rough polishing apparatus, consistent with aspects related to the innovations herein.

FIG. 2 is a graph showing exemplary warp distributions of implementations having different chemical-mechanical rough polishing slurries, consistent with aspects related to the innovations herein.

FIG. 3 is a graph showing exemplary TTV changes of implementations having different chemical-mechanical rough polishing slurries, consistent with aspects related to the innovations herein.

FIG. 4 is a graph showing exemplary LTV changes of implementations having different chemical-mechanical rough polishing slurries, consistent with aspects related to the innovations herein.

FIG. 5 is a graph showing exemplary BOW distributions of implementations having different chemical-mechanical rough polishing slurries, consistent with aspects related to the innovations herein.

FIG. 6 is a graph showing exemplary removal distribution(s) of implementations having different chemical-mechanical rough polishing slurries, consistent with aspects related to the innovations herein.

### DETAILED DESCRIPTION OF EXEMPLARY IMPLEMENTATIONS

Reference will now be made in detail to the invention, examples of which are illustrated in the accompanying drawings. The implementations set forth in the following description do not represent all implementations consistent with the disclosure. Instead, they are merely some examples consistent with certain aspects related to the disclosure. Wherever possible, the same reference numbers will be used throughout the drawings to refer to the same or like parts.

In one aspect the disclosure provides a chemical polishing slurry or solution for chemical rough polishing gallium arsenide (GaAs) wafers having an alkali metal dichloroisocyanurate or ammonium dichloroisocyanurate, an alkali metal acid pyrophosphate or ammonium pyrophosphate, a silica sol, an alkali metal bicarbonate or ammonium bicarbonate, an alkali metal sulfonate or ammonium sulfonate, and optionally water/one or more solvents.

In another aspect the disclosure provides a chemical-mechanical rough polishing solution having from about 8 to about 22% of an alkali metal dichloroisocyanurate or ammonium dichloroisocyanurate, from about 4.5 to about 19% (or about 4.5 to about 16%) of an alkali metal acid pyrophosphate or ammonium pyrophosphate, from about 55 to about 72% of silica sol, from about 3 to about 13% of an alkali metal bicarbonate or ammonium bicarbonate, and from about 0.01 to about 0.3% of an alkali metal sulfonate or ammonium sulfonate, based on a total weight of 100%, excluding water/solvents.

In yet another aspect the disclosure provides a chemical-mechanical rough polishing solution having from about 10 to about 20% of an alkali metal dichloroisocyanurate or ammonium dichloroisocyanurate, from about 8 to about 15% of an alkali metal acid pyrophosphate or ammonium pyrophosphate, from about 56 to about 69% of silica sol, from about 4.5 to about 11% of an alkali metal bicarbonate or ammonium bicarbonate, and from about 0.05 to about 0.3% of an alkali metal sulfonate or ammonium sulfonate, based on a total weight of 100%, excluding water/solvents.

In still another aspect the disclosure provides a chemical-mechanical rough polishing solution having from about 12 to about 18% of an alkali metal dichloroisocyanurate or ammonium dichloroisocyanurate, from about 9 to about 13% of an alkali metal acid pyrophosphate or ammonium pyrophosphate, from about 58 to about 68% (or about 60 to about 68%) of silica sol, from about 8 to about 10% of an alkali metal bicarbonate or ammonium bicarbonate, and from about 0.08 to about 0.5% of an alkali metal sulfonate or ammonium sulfonate, based on a total weight of 100%, excluding water/solvents.

According to some implementations, the total percentage by weight of the chemical components (i.e. dichloroisocyanurate, sulfonate, pyrophosphate, bicarbonate and silica sol) dissolved in water, based on the total weight of the resulting slurry, may be not higher than about 6%, or not higher than about 5%, or not higher than about 4%, or not higher than about 3%.

In some of the chemical-mechanical rough polishing slurries herein, dichloroisocyanurate, pyrophosphate, and bicarbonate may be any one of their water-soluble salts respectively. Further, dichloroisocyanurate, pyrophosphate, and bicarbonate may be any one of their water-soluble alkali metal salts or ammonium salts respectively, and more preferably any one of their sodium salts or ammonium salts respectively.

In some of the chemical-mechanical rough polishing slurries herein, sulfonate may be any one of water-soluble sulfonates, a water-soluble alkali metal or ammonium sulfonate, or a sodium or ammonium sulfonate. Further, sulfonate may be one selected from the group consisting of bisulfonate or monosulfonate of a C₆₋₁₆aryl group (i.e. an aromatic group containing 6 to 16 carbon atoms, including substituted phenyl) (such as C₄₋₁₀alkylbenzene sulfonate, benzene sulfonate, naphthalene sulfonate, anthracene sulfonate, C₄₋₁₀alkylbenzene disulfonate bi-salt, benzene disulfonate bi-salt, naphthalene di-sulfonate bi-salt or anthracene di-sulfonate bi-salt, for example, 1,2-benzenedisulfonic bi-salt, 1,3-benzenedisulfonic bi-salt, benzene sulfonate or naphthalene sulfonate), alkyl sulfonate (preferably sulfonate of an alkyl group of 4 to 10 carbon atoms, including butyl sulfonate, pentyl sulfonate, hexyl sulfonate, heptyl sulfonate, octyl sulfonate, nonyl sulfonate and decyl sulfonate) and phenolic sulfonate.

More preferably, sulfonate is 1,3-benzenedisulfonate, benzene sulfonate, naphthalene sulfonate or hexyl sulfonate.

For the purpose of preparing the innovative chemical-mechanical rough polishing slurry herein, silica sol can be a conventional silica sol, for example, a commercially available silica sol, or a freshly prepared silica sol prepared by a known process.

To prepare chemical-mechanical rough polishing slurries consistent with the innovations herein, all the chemical components may be directly introduced into, and then dissolved in deionized water, and then further/uniformly mixed. They can also be mixed thoroughly, then introduced into, and then dissolved in, deionized water, and then further/uniformly mixed. Alternatively, they may, one after another, be introduced into and then dissolved in deionized water, and then further/evenly mixed.

As confirmed by analysis and test results, when the chemical-mechanical rough polishing slurries prepared according to the innovations herein are stored in a sealed container, the Cl₂ that vaporizes from the solution into the airspace of the container is less than or equal to about 0.50 ml/m³ (calculated as under normal conditions, as elsewhere herein), and even less than or equal to about 0.45 ml/m³. Thus, it can be concluded that, compared with existing techniques, the innovations herein can decrease the vaporizing Cl₂ concentration in the airspace of a container and reduce environmental pollution.

Surprisingly, further analyses and results show that chemical-mechanical rough polishing slurries consistent with the innovations herein may be used after being stored for 24 hours from its preparation without compromising its effect. Thus, the chemical-mechanical rough polishing slurries herein do not require preparation and use at the moment of need; instead, they may be prepared beforehand and stored as stock solution. Thus, the innovations herein also entail reduced amounts of time needed, i.e., for preparation and operation/use in facilities.

Methods of chemical-mechanical rough polishing for performing chemical-mechanical rough polishing of a GaAs crystal wafers consistent with the innovations herein may comprise polishing the wafer in a chemical-mechanical rough polishing apparatus in the presence of a chemical-mechanical rough polishing slurry comprising, except water, dichloroisocyanurate, sulfonate, pyrophosphate, bicarbonate and silica sol.

Surprisingly, chemical-mechanical rough polishing slurries consistent with the innovations herein make it possible to achieve high polishing quality of wafers at low slurry concentrations. For example, in one exemplary implementation, based on the total weight of the chemical-mechanical rough polishing slurry, the total percentage of all the chemical components (i.e. dichloroisocyanurate, sulfonate, pyrophosphate, bicarbonate and silica sol, etc.) is not higher than about 3%. As such, the lower solid content leads to less crystallization of the chemical components in the chemical-mechanical rough polishing slurry and further contributes to reduced damages and scratches on the GaAs wafer, which increases the qualified product ratio or yield. Furthermore, such lower concentrations also facilitate lessening or removal of friction (saw) marks on the wafer, and provides for a more mirror-like wafer surface.

According to some exemplary implementations, chemical-mechanical rough polishing methods consistent with the innovations herein is not higher than about 3% based on the total weight of the chemical-mechanical rough polishing slurry, the total percentage of all the chemical components (i.e. dichloroisocyanurate, sulfonate, pyrophosphate, bicarbonate and silica sol).

All of the chemical-mechanical rough polishing slurries above may be used in the chemical-mechanical rough polishing methods for GaAs wafers consistent with the present innovations, and accordingly constitute different innovative implementations of the chemical-mechanical rough polishing methods herein. Also, the contents of the components described in connection with the various embodiments of the chemical-mechanical rough polishing slurries may be combined with each other to constitute different implementations of the chemical-mechanical rough polishing slurry and method of the invention respectively.

As a result of the chemical-mechanical rough polishing slurries and methods herein, GaAs wafers may be produced having less scratches, increased flatness, improved mirror-like surface, reduced cost, and/or involving less environmental pollution.

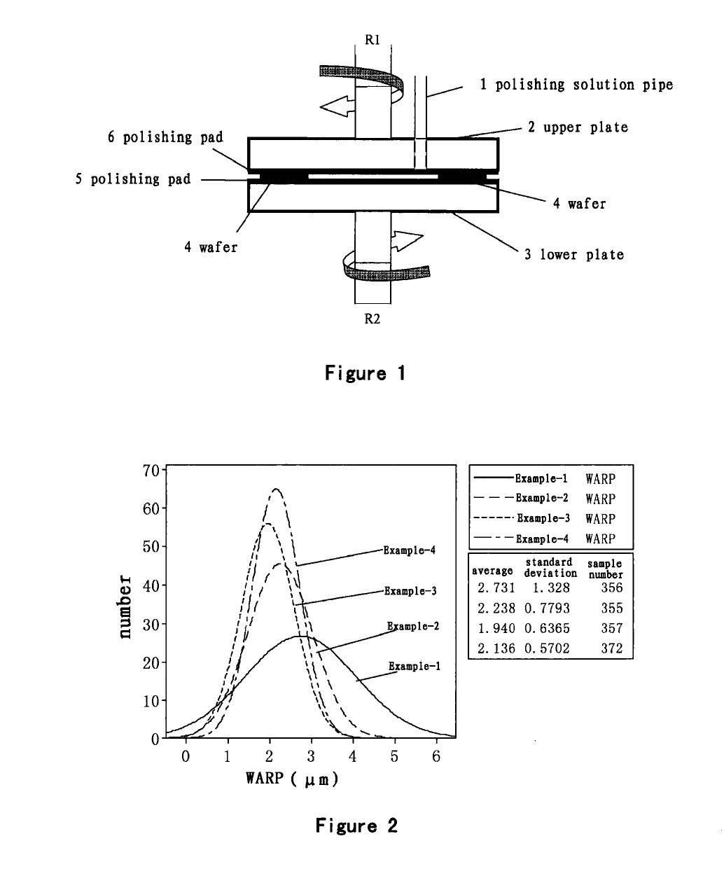

As exemplified in FIG. 1, the chemical-mechanical rough polishing method can be implemented as follows. A GaAs wafer 3 to be polished is loaded into a chemical-mechanical rough polishing equipment. The polishing equipment includes two parts, one above the other: plates 2 and 3, which on their surfaces facing each other are lined with polishing pads 5 and 6. GaAs wafer 4 is placed between the polishing pads 5 and 6. Plates 2 and 3 are rotated by driving shafts R1 and R2. For the purpose of carrying out the polishing process, the chemical-mechanical rough polishing slurry is supplied to the inside of the polishing equipment by a pipe from a storing container 1 for holding the chemical-mechanical rough polishing slurry. After being polished, the GaAs wafer is taken out from the polishing equipment, and then cleaned and dried.

According to one or more implementations, chemical-mechanical rough polishing methods consistent with the innovations here may be carried out in combination with a chemical fine polishing method. For example, chemical-mechanical rough polishing methods may be carried out first and then fine polishing, such as consistent with application Ser. No. 12/569,870, filed Sep. 29, 2009, published as US2010/______ A1, which is incorporated herein by reference in entirety, may then be carried out. All such aspects are consistent with the innovations herein.

The invention will be illustrated in the following by non-limiting examples.

### Examples 1-4

The chemical components of the chemical-mechanical rough polishing slurries (i.e. dichloroisocyanurate, sulfonate, pyrophosphate, bicarbonate and silica sol) were provided according to the formulation of Table 1 (based on the total weight of the solid contents), and mixed uniformly with deionized water (the concentration being based on the total weight of the resulting slurry), thus producing the chemical-mechanical rough polishing slurries. The formulated chemical-mechanical rough polishing slurry was stored in a 1,500 L sealed container for 24 hours. Then, Cl₂ concentrations in the airspace of the container and in the slurry were measured by using chlorine-Methyl orange spectrophotometric method. The results showed that Cl₂ vaporizing into the airspace in each container was less than 0.29 ml/m³ (calculated as under a normal condition), and that the effective chlorine concentration in the slurry after stored in a sealed container for 24 hours decreased by no more than 15% of its initial concentration. Calculations confirmed that the chemical-mechanical rough polishing slurries were stable and could be used within 24 hours after formulation without compromising its effect.

The formulated chemical-mechanical rough polishing slurries were used to carry out chemical-mechanical rough polishing of 152.4 mm (6 inch) diameter, 730 μm thick GaAs wafers in the rough polishing system of FIG. 1. The wafers were loaded with their centers spaced 200-400 mm from the center of the polishing equipment, 12-16 pieces in a batch, and underwent chemical-mechanical rough polishing for 20 minutes, with the lower and the upper plates of the polishing equipment rotating in opposite directions at indicated rates. Then the wafers were taken out, cleaned with deionized water, dried, and subjected to further measurement.

The conditions for chemical-mechanical rough polishing are shown in Table 2, wherein the removal rate was defined as the removal amount of the wafer (the difference of the thicknesses of the wafer before and after the polishing) divided by the time of polishing.

### Measurement Data/Information:

1. Surface roughness of the polished wafers, Ra, was measured by AFM (atomic force microscope), with Ra of less than 1 Å being acceptable (denoted with a √ on Table 1).
2. Yield was expressed as the ratio of the acceptable products after one polishing process, with yields of 98% or higher being acceptable (denoted with a √ on Table 1).
3. Flatness data, TTV (Total Thickness Variation) of <4.0 μm, LTV (Local Thickness Variation) of <1.5 μm at an area of 20 mm×2 mm, WARP (warp of the wafer) of <7 μm, and Bow (bend of wafer) of <3.0 μm, were within acceptable ranges (denoted with a √ on Table 1).
4. Removal rate was expressed as the removal amount of the wafer (the difference of the thicknesses of the wafer before and after the polishing) divided by the time of polishing.

The results of the above items 1-4 are shown on Table 1.
5. The flatness data of the wafers, including the data of WARP, TTV, LTV, and BOW, were collected by an Ultrosort instrument, Tropel, and analyzed by software, Minitab Special-6 Sigma analysis software, and also analyzed by histogram analysis method. The histogram was used to check the distribution of the data of the samples, which were simulated to constitute a smooth curve of distribution. The ordinate of the histogram represented the number of samples, referred to as number, on the respective abscissa.

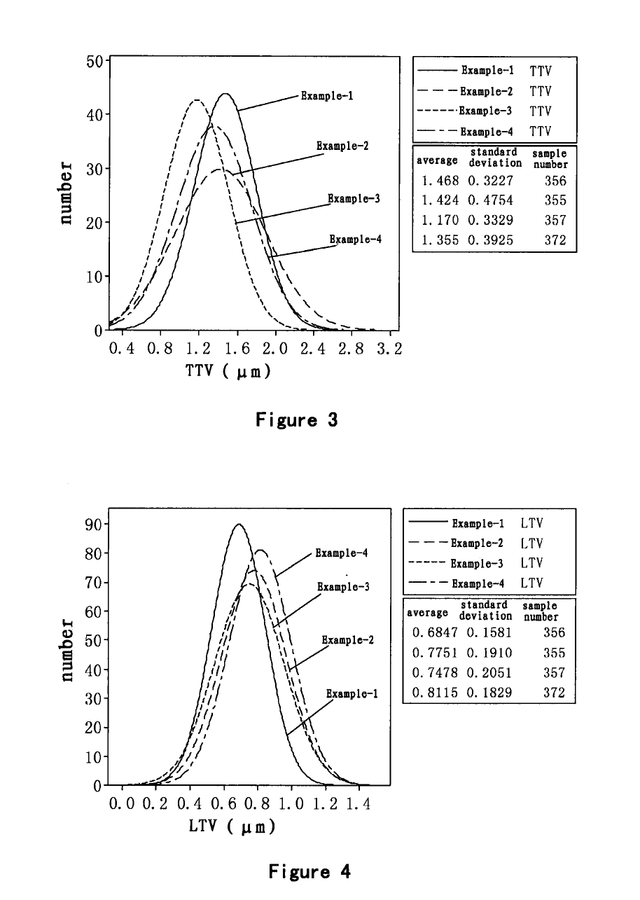

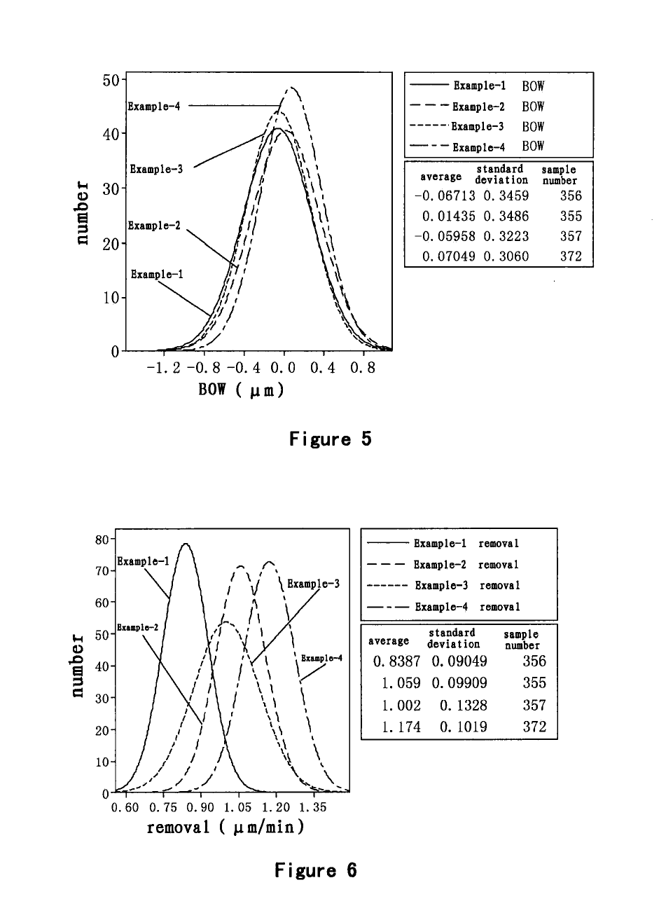

The results were shown in FIGS. 2-5, wherein the abscissa represented TTV, LTV, WARP or BOW, and the “average, standard deviation and sample number (sample numbers used in examples)”, from above to below, were for examples 1 to 4, respectively.
6. The wafer thickness data were collected with a contact thickness gauge, ID-C125EB, MIPUTOYO, Japan, and were analyzed by software, Minitab Special-6 Sigma analysis software, and also analyzed by histogram analysis method. The histogram was used to check the distribution of the data of the samples, which were simulated to constitute a smooth curve of distribution. The ordinate of the histogram represented the number of samples, referred to as number, on the respective abscissa.

Removal data were shown in FIG. 6, wherein the “average, standard deviation and sample number (sample numbers used in examples)”, from above to below, were for examples 1 to 4 respectively.

TABLE 1
Exemplary compositions of chemical-mechanical rough
polishing slurries and the experiment results

| Chemical components | Example 1 | Example 2 | Example 3 | Example 4 |
|---|---|---|---|---|
| Sodium dichloroiso- | 20.9 | 14.75 | 14.25 | 13.65 |
| cyanurate | | | | |
| Sodium pyrophosphate | 11.25 | 11.75 | 11.95 | 18.55 |
| Sodium bicarbonate | 8.8 | 8.6 | 9.26 | 9.6 |
| Sodium sulfonate | 0.1 | 0.12 | 0.14 | 0.2 |
| Silica sol | 56.95 | 64.78 | 64.5 | 70 |
| concentration of | 2.8 | 3 | 2.2 | 2.4 |
| Chemical components | | | | |
| (wt. %) | | | | |
| AFM | ✓ | ✓ | | ✓ |
| Yield | ✓ | ✓ | | ✓ |
| Flatness | ✓ | ✓ | | ✓ |
| Removal (μm/min) | 0.96 | 0.9 | 1.09 | 1.25 |

TABLE 2
Flow-rates of chemical-mechanical rough polishing
slurries and other polishing conditions

| Polishing conditions | Example 1 | Example 2 | Example 3 | Example 4 |
|---|---|---|---|---|
| Pressure on the wafers, | 72 | 80 | 72 | 68 |
| g/cm² | | | | |
| Flow-rate of the slurries, | 80 | 100 | 90 | 120 |
| l/hour | | | | |
| Rotating velocity, rpm | 41 | 38 | 35 | 43 |

While the present disclosure has been particularly shown and described with reference to several implementations thereof, it will be understood by those of ordinary skill in the art that various changes in form and details may be made thereto without departing from the principles and spirit of the present disclosure, the proper scope of which is defined in the following claims and their equivalents.

1. A chemical-mechanical rough polishing slurry for the chemical-mechanical rough polishing of a GaAs wafer, comprising, excluding aqueous solvent, dichloroisocyanurate, sulfonate, pyrophosphate, bicarbonate and silica sol.

2. The chemical-mechanical rough polishing slurry according to claim 1, comprising about 8 to about 22% dichloroisocyanurate, about 0.01 to about 0.3% sulfonate, about 4.5 to about 16% pyrophosphate, about 3 to about 13% bicarbonate and about 55 to about 72% silica sol, by weight based on the solute, excluding the aqueous solvent, out of a total weight of 100%.

3. The chemical-mechanical rough polishing slurry according to claim 2, comprising about 10 to about 20% dichloroisocyanurate, about 0.05 to about 0.3% sulfonate, about 8 to about 15% pyrophosphate, about 4.5 to about 11% bicarbonate and about 56 to about 69% silica sol, by weight based on the solute, excluding the aqueous solvent.

4. The chemical-mechanical rough polishing slurry according to claim 3, comprising about 12 to about 18% dichloroisocyanurate, about 0.08 to about 0.5% sulfonate, about 9 to about 13% pyrophosphate, about 8 to about 10% bicarbonate and about 58 to about 68% silica sol, by weight based on the solute, excluding the aqueous solvent.

5. The chemical-mechanical rough polishing slurry according to claim 1, wherein the total percentage by weight of dichloroisocyanurate, sulfonate, pyrophosphate, bicarbonate and silica sol in the chemical-mechanical rough polishing slurry is not higher than about 3%.

6. The chemical-mechanical rough polishing slurry according to claim 1, wherein one or more of the dichloroisocyanurate, the solfonate, the pyrophosphate, and the bicarbonate are in water-soluble alkali metal salt or ammonium salt form.

7. The chemical-mechanical rough polishing slurry according to claim 6, wherein one or more of the dichloroisocyanurate, the solfonate, the pyrophosphate, and the bicarbonate are in sodium salt or ammonium salt form.

8. The chemical-mechanical rough polishing slurry according to claim 7, wherein one or more of the dichloroisocyanurate, the solfonate, the pyrophosphate, and the bicarbonate are in sodium salt form.

9. A chemical-mechanical rough polishing method for performing chemical-mechanical rough polishing of a GaAs crystal wafer, comprising polishing said wafer in a chemical-mechanical rough polishing apparatus in the presence of a chemical-mechanical rough polishing slurry as set forth claim 1.

10. A system for chemical-mechanical rough polishing of GaAs crystal wafers, the system comprising:
a platform for holding a GaAs wafer;
a polishing pad to contact the wafer;
a polishing slurry according to claim 1.
